(19) United States
(12) Patent Application Publication
(10) Pub. No.: US 2006/0044750 A1
(43) Pub. Date: Mar. 2, 2006

(54) Electronic device and fixing structure thereof

(75) Inventor: Chien Ying Chen, Taipei (TW)

Correspondence Address: BIRCH STEWART KOLASCH & BIRCH, PO BOX 747, FALLS CHURCH, VA, 22040-0747, US

(73) Assignee: ASUSTeK COMPUTER INC.

(21) Appl. No.: 11/205,152

(22) Filed: Aug. 17, 2005

(30) Foreign Application Priority Data
Aug. 26, 2004 (TW) 093125639

(51) Int. Cl. G06F 1/16; H05K 5/00

(52) U.S. Cl. 361/685

(57) ABSTRACT

A fixing structure fixes a removable electronic device. The removable electronic device has a first opening. The fixing structure includes a chassis and a movable member. In this case, the chassis has a second opening and a first connection arm. The second opening is opposite to the first opening. The movable member is pivoted on the chassis. The movable member has at least a protruding portion and a third opening. A second connection arm is disposed on the movable member. When the movable member contacts with the chassis, the protruding portion passes through the second opening and inserts into the first opening, and the first connection arm inserts into the third opening and buckles the second connection arm.

### BACKGROUND OF THE INVENTION

1. Field of Invention

The invention relates to an electronic device and a fixing structure thereof and, in particular, to an electronic device having a movable member and a fixing structure thereof.

2. Related Art

In the information era, the hard disk drive (HDD) is one of the most important storage devices in a computer. It provides cheap, high-speed and large-capacity storage space for storing the operating system, application programs, and users' data.

In addition to the HDD, another data storage devices are optical information storage media. To access such media, one has to use an optical disk drive. Therefore, both the HDD and the optical disk drive are important devices in a computer.

A normal removable HDD or a removable optical disk drive is fixed on a cage that is one part of a host. As shown in FIG. 1, the conventional removable HDD 11 is accommodated in a cage 12. The sides of the cage 12 have several screw holes 121 corresponding to the fixing holes 111 on the sides of the HDD 11. Therefore, the HDD 11 can be fixed in the cage 12 by using screws 13.

However, the mounting and release of the removable HDD 11 rely on the use of many screws 13. This does not only waste the assembly time and lower the production speed, but the screws also cost a lot. Moreover, if threads of the screws 13 are destroyed, the screws 13 have to be changed. As the result, in the method of the prior art for fixing the removable HDD 11, the production costs may be increased.

Further, when the removable HDD 11 needs to be maintained or changed, the user has to use a screwdriver to remove the screws. However, the screwdriver is easy to lose, it may interrupt the progress of the working.

It is therefore an important subject of the present invention to provide an electronic device and a fixing structure thereof to reduce the use of the screws and simplify the process of the assembly.

### SUMMARY OF THE INVENTION

In view of the foregoing, the present invention is to provide an electronic device and a fixing structure thereof, wherein the removable electronic device can be fixed on the chassis without screws.

To achieve the above, a fixing structure according to the present invention is for fixing a removable electronic device. The removable electronic device has a first opening. The fixing structure includes a chassis and a movable member. In this case, the chassis has a second opening and a first connection arm. The second opening is opposite to the first opening. The movable member is pivoted on the chassis. The movable member has at least a protruding portion and a third opening. A second connection arm is disposed on the movable member. When the movable member contacts with the chassis, the protruding portion passes through the second opening and inserts into the first opening, and the first connection arm inserts into the third opening and buckles the second connection arm.

To achieve the above, an electronic device according to the present invention has a fixing structure. The electronic device includes a removable electronic component, a chassis and a movable member. In this case, the removable electronic component has at least a first opening. The chassis has a second opening and a first connection arm. The second opening is opposite to the first opening. The movable member is pivoted on the chassis. The movable member has at least a protruding portion and a third opening. A second connection arm is disposed on the movable member. When the movable member contacts with the chassis, the protruding portion passes through the second opening and inserts into the first opening. The first connection arm inserts into the third opening and buckles the second connection arm.

As mentioned above, an electronic device and a fixing structure thereof according to the present invention have a movable member pivoted on a chassis. Comparing to the prior art, the chassis has a first connection arm, and the movable member has a second connection arm. The protruding portion passes through the second opening and inserts into the first opening, and the first connection arm buckles the second connection arm, so that the removable electronic device can be fixed on the chassis. Because the removable electronic device can be fixed on the chassis without screws, the time required for assembly and the production cost may be reduced. Furthermore, in the present invention, the removable electronic device can be released from the chassis by pressing the pressing portion of the second connection arm. Also, the removable electronic device can be fixed on or released from the chassis without tools. Because of the above, it is particularly convenient and labor-saving for the users. Moreover, the fixing structure of the present invention can fix more than two removable electronic devices, so the assembly rate may be increased.

### BRIEF DESCRIPTION OF THE DRAWINGS

The present invention will become more fully understood from the detailed description given herein below illustration only, and thus is not limitative of the present invention, and wherein:

FIG. 1 is a schematic view showing a conventional removable hard disc drive;

FIG. 2 is a schematic view showing an electronic device and a fixing structure thereof according to the preferred embodiment of the present invention;

FIG. 3 is another schematic view showing the electronic device and the fixing structure thereof according to the preferred embodiment of the present invention;

FIG. 4 is a schematic view showing the fixing structure according to the preferred embodiment of the present invention;

FIG. 5 is a schematic view showing a movable member according to the preferred embodiment of the present invention;

FIG. 6 is the other schematic view showing the electronic device and the fixing structure thereof according to the preferred embodiment of the present invention, wherein the movable electronic device is fixed on the chassis;

FIG. 7 is an enlarged view showing a dotted line portion of FIG. 2; and

FIG. 8 is an enlarged view showing a dotted line portion of FIG. 3.

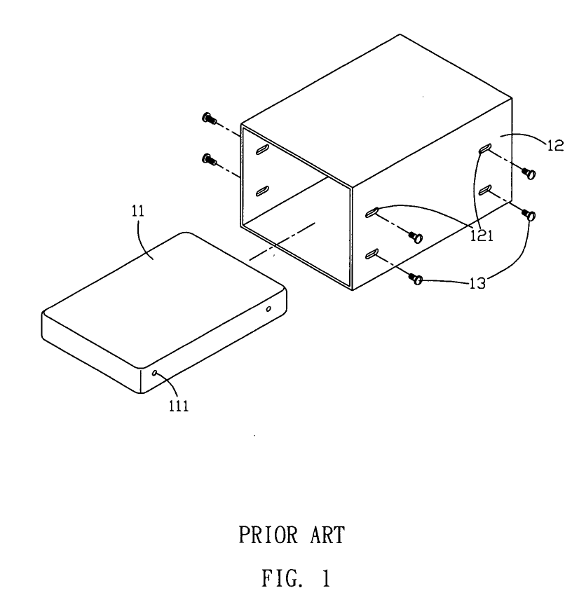

### DETAILED DESCRIPTION OF THE INVENTION

The present invention will be apparent from the following detailed description, which proceeds with reference to the accompanying drawings, wherein the same references relate to the same elements.

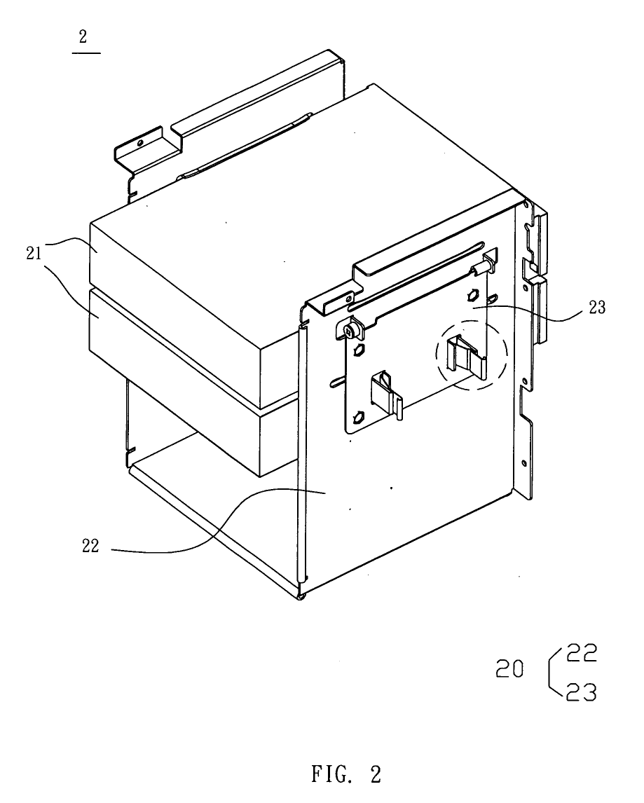

Please refer to FIG. 2 to FIG. 8 for illustrating an electronic device 2 according to a preferred embodiment of the present invention.

As shown in FIG. 2, the electronic device 2 according to the preferred embodiment of the present invention includes a removable electronic component 21, a chassis 22, and a movable member 23. Herein, the electronic device 2 may have one removable electronic component 21. Also, the electronic device 2 may have two removable electronic components 21. In the present embodiment, the electronic device 2 has two removable electronic components 21.

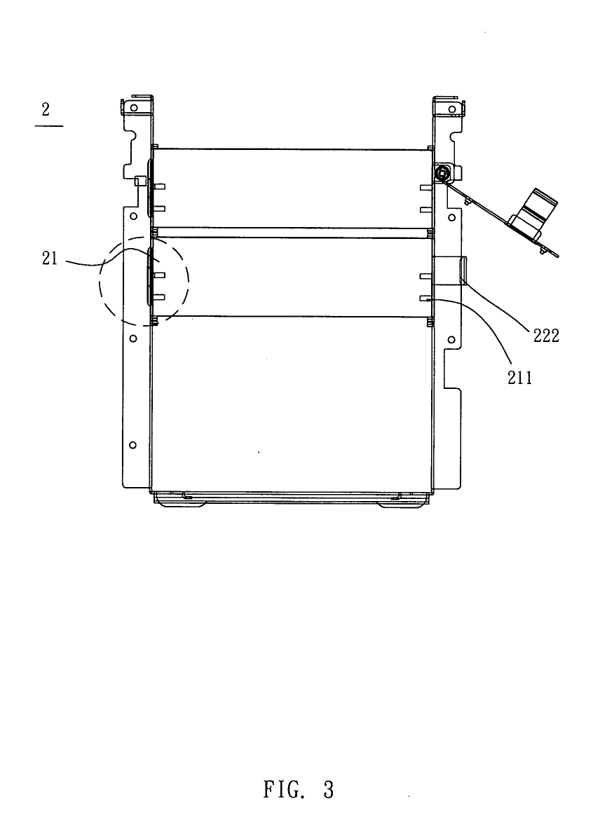

Please refer to FIG. 3, the removable electronic component 21 has at least a first opening 211. In the present embodiment, the removable electronic component 21 may be a hard disc drive or a CD-ROM drive.

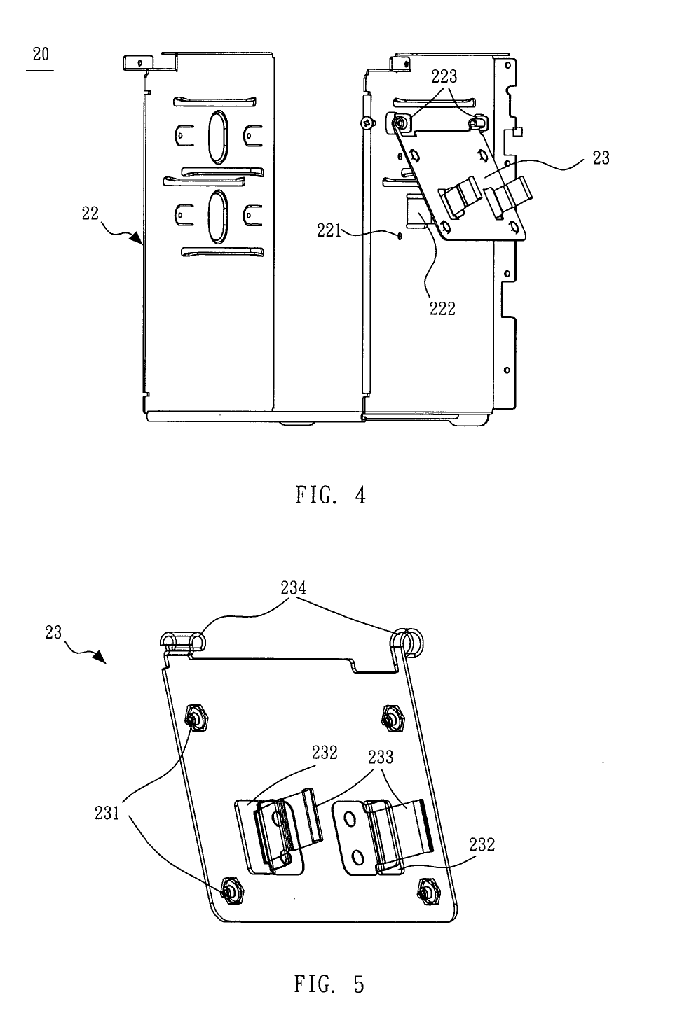

As shown in FIG. 3 and FIG. 4, the chassis 22 has a second opening 221 and a first connection arm 222. The second opening 221 is opposite to the first opening 211. In the present embodiment, the chassis 22 has two first connection arms 222. The first connection arms 222 are fixed on the chassis 22. Herein, the first connection arms 222 are fixed on the chassis 22 by way of welding. Of course, the number of the first connection arm 222 may be adjustable by the real needs. Also, the first connection arm 222 and the chassis 22 may be in one piece.

Please refer to FIG. 4 and FIG. 5, the movable member 23 is pivoted on the chassis 22. The chassis 22 further has at least a first pivoting portion 223. The movable member 23 is rotatable about the first pivoting portion 223. The movable member 23 has at least a protruding portion 231 and a third opening 232. A second connection arm 233 is disposed on the movable member 23. Herein, the protruding portion 231 may be a rivet. The second connection arm 233 may be fixed on the fixing member 23. Herein, the second connection arm 233 may be fixed on the fixing member 23 by way of welding. In the present embodiment, the movable member 23 has at least a second pivoting portion 234 pivoted with the first pivoting portion 223.

Herein, a fixing structure 20 for fixing the removable electronic component 21 includes the chassis 22 and the movable member 23.

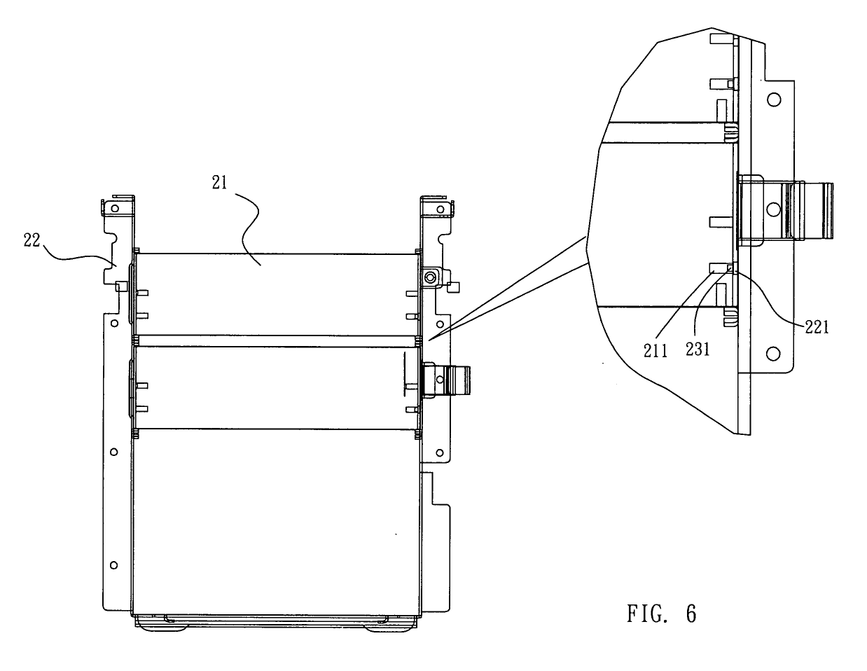

Please refer to FIG. 5 and FIG. 6, when the movable member 23 contacts with the chassis 22, the protruding portion 231 passes through the second opening 221 and inserts into the first opening 211. The first connection arm 222 inserts into the third opening 232 and buckles the second connection arm 233. Hence, the movable electronic component 21 is fixed on the chassis 22.

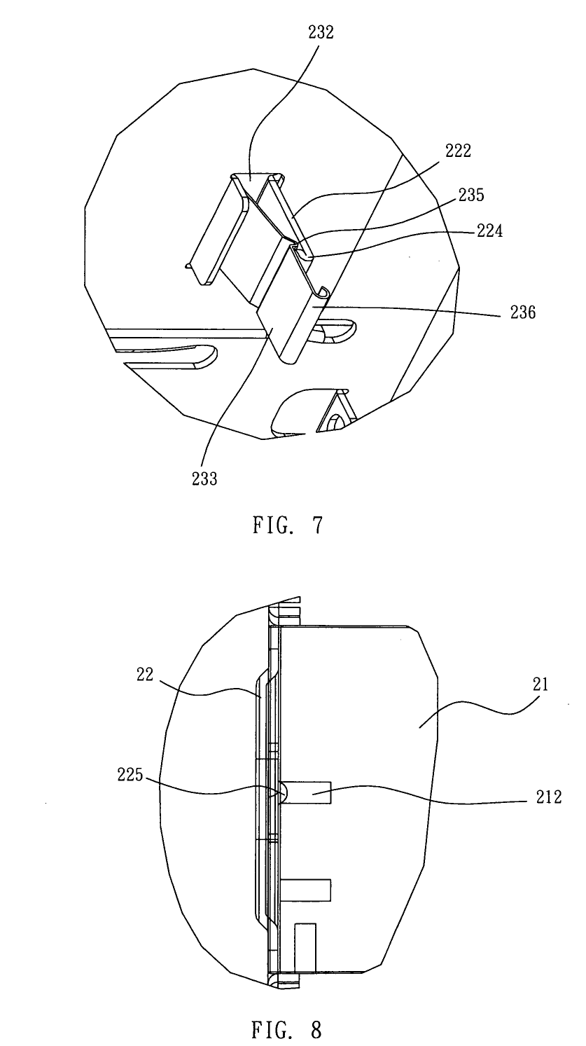

Please refer to FIG. 7, the first connection arm 222 has a hook portion 224, and the second connection arm 223 has a fold portion 235. When the hook portion 224 touch with the fold portion 235, the first connection arm 222 locks the second connection arm 233.

Please refer to FIG. 3 and FIG. 8 again, in the present embodiment, the removable electronic component 21 further includes a fourth opening 212. The fourth opening 212 is disposed on one side of the removable electronic component 21, and the first opening 211 is disposed on the other side of the removable electronic component 21. The chassis 22 has a fixing portion 225 opposite to the fourth opening 212. The fixing portion 225 may be a protrusion made by punching. When the movable member 23 contacts with the chassis 22, the fixing portion 225 inserts into the fourth opening 212. Because of the above, both sides of the removable electronic component 21 may be fixed on the chassis 22.

As shown in FIG. 2 and FIG. 7, in the present embodiment, the second connection arm 223 further includes a pressing portion 236. When a force presses the pressing portion 236, the hook portion 224 is away from the fold portion 235, so that the lock status between the first connection arm 222 and the second connection arm 233 may be released.

Please refer to FIG. 2 to FIG. 8 again for illustrating a fixing structure 20 for fixing a removable electronic component 21 according to another preferred embodiment of the present invention, wherein the same references relate to the same elements.

Please refer to FIG. 2 and FIG. 4, the fixing structure 20 according to the present invention is for fixing the removable electronic component 21. Herein, the fixing structure 20 may fix one removable electronic component 21. Also, the fixing structure 20 may fix two removable electronic components 21. In the present embodiment, the fixing structure 20 may fix two removable electronic components 21. Herein, the removable electronic component 21 has at least a first opening 211. In the present embodiment, the removable electronic component 21 may be a hard disc drive or a CD-ROM drive.

As shown in FIG. 4, the fixing structure 20 of the present invention includes a chassis 22 and a movable member 23.

As shown in FIG. 3 and FIG. 4, the chassis 22 has a second opening 221 and a first connection arm 222. The second opening 221 is opposite to the first opening 211. In the present embodiment, the chassis 22 has two first connection arms 222. The first connection arms 222 are fixed on the chassis 22. Herein, the first connection arms 222 are fixed on the chassis 22 by way of welding. Of course, the number of the first connection arm 222 may be adjustable by the real needs. Also, the first connection arm 222 and the chassis 22 may be in one piece.

Please refer to FIG. 4 and FIG. 5, the movable member 23 is pivoted on the chassis 22. The chassis 22 further has at least one first pivoting portion 223. The movable member 23 is rotatable about the first pivoting portion 223. The movable member 23 has at least a protruding portion 231 and a third opening 232. A second connection arm 233 is disposed on the movable member 23. Herein, the protruding portion 231 may be a rivet. The second connection arm 233 may be fixed on the fixing member 23. Herein, the second connection arm 233 may be fixed on the fixing member 23 by way of welding. In the present embodiment, the movable member 23 has at least a second pivoting portion 234 pivoted with the first pivoting portion 223.

Herein, the fixing structure 20 for fixing the removable electronic component 21 includes the chassis 22 and the movable member 23.

Please refer to FIG. 4, FIG. 5 and FIG. 6, when the movable member 23 contacts with the chassis 22, the protruding portion 231 passes through the second opening 221 and inserts into the first opening 211. The first connection arm 222 inserts into the third opening 232 and buckles the second connection arm 233. Hence, the movable electronic component 21 can be fixed on the chassis 22.

Please refer to FIG. 7, the first connection arm 222 has a hook portion 224, and the second connection arm 223 has a fold portion 235. When the hook portion 224 touch with the fold portion 235, the first connection arm 222 locks the second connection arm 233.

Please refer to FIG. 3 and FIG. 8, in the present embodiment, the removable component 21 further includes a fourth opening 212. The fourth opening 212 is disposed on one side of the removable electronic component 21, and the first opening 211 is disposed on the other side of the removable electronic component 21. The chassis 22 has a fixing portion 225 is opposite to the fourth opening 212. The fixing portion 225 may be a protrusion made by punching. When the movable member 23 contacts with the chassis 22, the fixing portion 225 inserts into the fourth opening 212. Because of the above, both sides of the removable electronic component 21 may be fixed on the chassis 22.

As shown in FIG. 2 and FIG. 7, in the present embodiment, the second connection arm 233 further includes a pressing portion 236. When a force presses the pressing portion 236, the hook portion 224 is away from the fold portion 235, so that the lock status between the first connection arm 222 and the second connection arm 233 may be released.

As mentioned above, an electronic device and a fixing structure thereof according to the present invention have a movable member pivoted on a chassis. Comparing to the prior art, the chassis has a first connection arm, and the movable member has a second connection arm. The protruding portion passes through the second opening and inserts into the first opening, and the first connection arm buckles the second connection arm, so that the removable electronic device is fixed on the chassis. Because the removable electronic device can be fixed on the chassis without screws, the time required for assembly and the production cost may be reduced. Furthermore, in the present invention, the removable electronic device can be released from the chassis by pressing the pressing portion of the second connection arm. Also, the removable electronic device can be fixed on or released from the chassis without tools. Because of the above, it is particularly convenient and labor-saving for the users. Moreover, the fixing structure of the present invention can fix more than two removable electronic devices, so the assembly rate may be increased.

Although the present invention has been described with reference to specific embodiments, this description is not meant to be construed in a limiting sense. Various modifications of the disclosed embodiments, as well as alternative embodiments, will be apparent to persons skilled in the art. It is, therefore, contemplated that the appended claims will cover all modifications that fall within the true scope of the present invention.

What is claimed is:

1. A fixing structure for fixing a removable electronic component, wherein the removable electronic component has a first opening, the fixing structure comprising:
a chassis, which has a second opening and a first connection arm, wherein the second opening is opposite to the first opening; and
a movable member, which is pivoted on the chassis, wherein the movable member has at least a protruding portion and a third opening, a second connection arm is disposed on the movable member, when the movable member contacts with the chassis, the protruding portion passes through the second opening and inserts into the first opening, and the first connection arm inserts into the third opening and buckles the second connection arm.

2. The fixing structure according to claim 1, wherein the removable electronic component further comprises a fourth opening, the fourth opening is disposed on one side of the removable electronic component, and the first opening is disposed on the other side of the removable electronic component, the chassis has a fixing portion opposite to the fourth opening.

3. The fixing structure according to claim 2, wherein when the movable member contacts with the chassis, the fixing portion inserts into the fourth opening.

4. The fixing structure according to claim 2, wherein the fixing portion is a protrusion made by punching.

5. The fixing structure according to claim 1, wherein the first connection arm connects with the chassis.

6. The fixing structure according to claim 1, wherein the first connection arm and the chassis are in one piece.

7. The fixing structure according to claim 1, wherein the chassis further comprises a first pivoting portion, the movable member is rotatable about the first pivoting portion.

8. The fixing structure according to claim 7, wherein the movable member has at least a second pivoting portion pivoted with the first pivoting portion.

9. The fixing structure according to claim 1, wherein the protruding portion is a rivet.

10. The fixing structure according to claim 1, wherein the first connection arm has a hook portion, the second connection arm has a fold portion, when the hook portion touches with the fold portion, the first connection arm locks the second connection arm.

11. An electronic device having a fixing structure, comprising:
a removable electronic component, which has at least a first opening;
a chassis, which has a second opening and a first connection arm, wherein the second opening is opposite to the first opening; and
a movable member, which is pivoted on the chassis, wherein the movable member has at least a protruding portion and a third opening, a second connection arm is disposed on the movable member, when the movable member contacts with the chassis, the protruding portion passes through the second opening and inserts into the first opening, and the first connection arm inserts into the third opening and buckles the second connection arm.

12. The electronic device according to claim 11, wherein the removable electronic component further comprises a fourth opening, the fourth opening is disposed on one side of the removable electronic component, and the first opening is disposed on the other side of the removable electronic component, the chassis has a fixing portion is opposite to the fourth opening.

13. The electronic device according to claim 12, wherein when the movable member contacts with the chassis, the fixing portion inserts into the fourth opening.

14. The electronic device according to claim 12, wherein the fixing portion is a protrusion made by punching.

15. The electronic device according to claim 11, wherein the first connection arm connects with the chassis.

16. The electronic device according to claim 11, wherein the first connection arm and the chassis are in one piece.

17. The electronic device according to claim 11, wherein the chassis further comprises a first pivoting portion, the movable member is rotatable about the first pivoting portion.

18. The electronic device according to claim 17, wherein the movable member has at least a second pivoting portion pivoted with the first pivoting portion.

19. The electronic device according to claim 11, wherein the protruding portion is a rivet.

20. The electronic device according to claim 11, wherein the first connection arm has a hook portion, the second connection arm has a fold portion, when the hook portion touch with the fold portion, the first connection arm locks the second connection arm.
